(19) United States
(12) Patent Application Publication
(10) Pub. No.: US 2021/0410276 A1
(43) Pub. Date: Dec. 30, 2021

(54) Method and Device of Managing Materials

(71) Applicant: Wuhan China Star Optoelectronics Technology Co., LTD., Wuhan, Hubei (CN)

(72) Inventor: Pengfei YU, Wuhan, Hubei (CN)

(73) Assignee: Wuhan China Star Optoelectronics Technology Co., LTD., Wuhan, Hubei (CN)

(21) Appl. No.: 16/485,439

(22) PCT Filed: Apr. 26, 2019
(86) PCT No.: PCT/CN2019/084424

§ 371 Date: Aug. 12, 2019

(30) Foreign Application Priority Data
Nov. 29, 2018 (CN) 201811446801.5

(51) Int. Cl. H05K 1/02; G02F 1/1333; G06K 19/06; G06K 19/07

(52) U.S. Cl. CPC H05K 1/0266; G06K 19/0722; G06K 19/06037; G02F 1/1333

(57) ABSTRACT

The present application provides a method and device of managing materials. In processes of manufacturing display devices, circuit board identifiers of flexible circuit boards and panel identifiers of display panels are obtained, and then the circuit board identifiers are bound with the panel identifiers. In a later stage, material management is performed on the display panels according to the circuit board identifiers. Based on the circuit board identifiers, sources of the display panels can be traced, so that no industrial inkjet printers are required and thus costs of material management can be reduced.

### BACKGROUND OF INVENTION

### 1. Field of Invention

The present invention relates to a technical field of displays, and particularly, to a method and a device of managing materials.

### 2. Related Art

Display panels are important parts of display devices, so that quality of display panels has significant influence on the display devices.

In current technology, in-plant identification tags are generated according to identifiers of display panels, such as two-dimensional codes, etc. Then, the in-plant identification tags are sprayed on backlight plates of display devices, so that material management of the display panels can be carried out based on the in-plant identification tags. However, industrial inkjet printers are required to perform the aforementioned material management method and thus give rise to high costs of doing so.

Therefore, how to implement material management for sources of display panels at a low cost has become an issue to people skilled in the art.

### SUMMARY OF INVENTION

The present application provides a method and device of managing materials to overcome a technical problem that industrial inkjet printers are required for conventional material management technology.

To overcome the aforementioned problem, the present application provides a technical solution as follows:

An embodiment of the present application provides a method of managing materials, comprising obtaining circuit board identifiers of flexible circuit boards and panel identifiers of display panels from binding targets; binding the circuit board identifiers with the panel identifiers; and performing material management on the display panels according to the circuit board identifiers.

In the method of managing materials of the present application, the binding the circuit board identifiers with the panel identifiers comprises obtaining, by encrypting the circuit board identifiers, first encrypted identifiers; and establishing a first mapping relationship between the first encrypted identifiers and the panel identifiers, wherein the first encrypted identifiers are in a one-to-one correspondence with the panel identifiers in the first mapping relationship.

In the method of managing materials of the present application, the binding the circuit board identifier with the panel identifier comprises obtaining, by encrypting the panel identifiers, second encrypted identifiers; and establishing a second mapping relationship between the circuit board identifiers and the second encrypted identifiers, wherein the circuit board identifiers are in a one-to-one correspondence with the second encrypted identifiers in the second mapping relationship.

In the method of managing materials of the present application, the binding the circuit board identifier with the panel identifier comprises establishing a third mapping relationship between the circuit board identifiers and the panel identifiers, wherein the circuit board identifiers are in a one-to-one correspondence with the panel identifiers in the third mapping relationship.

In the method of managing materials of the present application, the binding the circuit board identifier with the panel identifier comprises generating first binding identifiers comprising the circuit board identifiers and the panel identifiers.

In the method of managing materials of the present application, the binding the circuit board identifier with the panel identifier comprises generating second binding identifiers comprising the circuit board identifiers, the panel identifiers, and timestamps.

In the method of managing materials of the present application, the binding the circuit board identifier with the panel identifier comprises generating third binding identifiers comprising the circuit board identifiers, the panel identifiers, and binding machine identifiers.

In the method of managing materials of the present application, the binding the circuit board identifier with the panel identifier comprises generating fourth binding identifiers comprising the circuit board identifiers, the panel identifiers, timestamps, and binding machine identifiers.

In the method of managing materials of the present application, the obtaining circuit board identifiers of flexible circuit boards and panel identifiers of display panels from binding targets comprises binding the flexible circuit boards with the display panels; and obtaining the circuit board identifiers of the flexible circuit boards and the panel identifiers of the display panels.

In the method of managing materials of the present application, the performing material management on the display panels according to the circuit board identifiers comprises performing a fully fitting process of covers; obtaining the circuit board identifiers; determining the panel identifiers based on the circuit board identifiers; and posting the display panels according to the panel identifiers.

An embodiment of the present application further provides a device of managing materials, comprising an obtaining module configured to obtain circuit board identifiers of flexible circuit boards and panel identifiers of display panels from binding targets; a binding module configured to bind the circuit board identifiers with the panel identifiers; and a managing module configured to perform material management on the display panels according to the circuit board identifiers.

In the device of managing materials of the present application, the obtaining module is configured to bind the flexible circuit boards and the display panels, and obtain the circuit board identifiers of the flexible circuit boards and the panel identifiers of the display panels.

In the device of managing materials of the present application, the obtaining module is configured to package chips and the display panels to obtain first package bodies, and to package the flexible circuit boards and the first to obtain second package bodies.

In the device of managing materials of the present application, the binding module is configured to encrypt the circuit board identifiers to obtain first encrypted identifiers, and to establish a first mapping relationship between the first encrypted identifiers and the panel identifiers, wherein the first encrypted identifiers are in a one-to-one correspondence with the panel identifiers in the first mapping relationship.

In the device of managing materials of the present application, the binding module is configured to encrypt the panel identifiers to obtain second encrypted identifiers, and to establish a second mapping relationship between the circuit board identifiers and the second encrypted identifiers, wherein the circuit board identifiers are in a one-to-one correspondence with the second encrypted identifiers in the second mapping relationship.

In the device of managing materials of the present application, the binding module is configured to establish a third mapping relationship between the circuit board identifiers and the panel identifiers, wherein the circuit board identifiers are in a one-to-one correspondence with the panel identifiers in the third mapping relationship.

In the device of managing materials of the present application, the binding module is configured to generate first binding identifiers comprising the circuit board identifiers and the panel identifiers.

In the device of managing materials of the present application, the binding module is configured to generate second binding identifiers comprising the circuit board identifiers, the panel identifiers, and timestamps.

In the device of managing materials of the present application, the binding module is configured to generate third binding identifiers comprising the circuit board identifiers, the panel identifiers, timestamps, and binding machine identifiers.

In the device of managing materials of the present application, the binding module is configured to generate fourth binding identifiers comprising the circuit board identifiers, the panel identifiers, timestamps, and binding machine identifiers.

The application has advantageous effects as follows: the present application provides a novel method of managing materials, wherein in processes of manufacturing display devices, circuit board identifiers of flexible circuit boards and panel identifiers of display panels are obtained, and then the circuit board identifiers are bound with the panel identifiers. In a later stage, material management is performed on the display panels according to the circuit board identifiers. Due to uniqueness of the flexible circuit boards, sources of the display panels can be traced based on the circuit board identifiers. The aforementioned method is implemented without generating in-plant identification tags, so that no in-plant identification tags are needed to be sprayed on backlight plates of the display devices and no industrial inkjet printers are required, thereby overcoming a technical problem that industrial inkjet printers are required for conventional material management technology, and lowering costs of material management.

### BRIEF DESCRIPTION OF DRAWINGS

To describe the technical solutions in the embodiments of the present invention, the following briefly introduces the accompanying drawings for describing the embodiments. Apparently, the accompanying drawings in the following description show merely some embodiments of the present invention, and a person skilled in the art may still derive other drawings from these accompanying drawings without creative efforts.

FIG. 1 is a flowchart showing a method of managing materials of an embodiment of the present application.

FIG. 2 is schematic view of a device of managing materials of an embodiment of the present application.

FIG. 3 is a schematic view showing a comparison of backlight panels.

### DESCRIPTION OF PREFERRED EMBODIMENTS

The following embodiments are referring to the accompanying drawings for exemplifying specific implementable embodiments of the present invention. Directional terms described by the present invention, such as upper, lower, front, back, left, right, inner, outer, side, etc., are only directions by referring to the accompanying drawings, and thus the used directional terms are used to describe and understand the present invention, but the present invention is not limited thereto.

Embodiments of the present application are provided to overcome a technical problem that industrial inkjet printers are required for conventional material management technology.

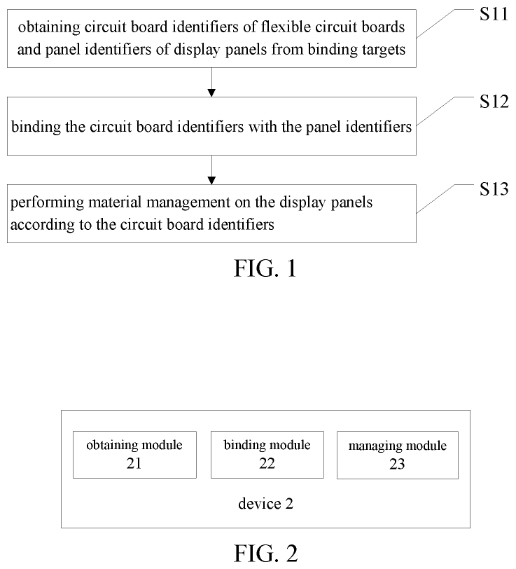

In one embodiment, as shown in FIG. 1, a method of managing materials includes following steps:

S11: obtaining circuit board identifiers of flexible circuit boards and panel identifiers of display panels from binding targets.

In one embodiment, step S11 includes: binding the flexible circuit boards with the display panels; and obtaining the circuit board identifiers of the flexible circuit boards and the panel identifiers of the display panels.

In one embodiment, the step of binding the flexible circuit boards with the display panels includes: package chips and the display panels to obtain first package bodies, and to package the flexible circuit boards and the first to obtain second package bodies.

S12: binding the circuit board identifiers with the panel identifiers. In the present application, the step may be implemented in a variety of ways.

In one embodiment, step S12 includes: obtaining first encrypted identifiers by encrypting the circuit board identifiers; and establishing a first mapping relationship between the first encrypted identifiers and the panel identifiers, wherein the first encrypted identifiers are in a one-to-one correspondence with the panel identifiers in the first mapping relationship. The encrypted circuit board identifiers of the present embodiment ensure information security.

In one embodiment, step S12 includes: obtaining second encrypted identifiers by encrypting the panel identifiers; and establishing a second mapping relationship between the circuit board identifiers and the second encrypted identifiers, wherein the circuit board identifiers are in a one-to-one correspondence with the second encrypted identifiers in the second mapping relationship. The encrypted panel identifiers of the present embodiment ensure information security.

In one embodiment, step S12 includes: establishing a third mapping relationship between the circuit board identifiers and the panel identifiers, wherein the circuit board identifiers are in a one-to-one correspondence with the panel identifiers in the third mapping relationship. In this manner, no encryption process is required, ensuring binding speed.

In one embodiment, step S12 includes: generating first binding identifiers including the circuit board identifiers and the panel identifiers. This embodiment provides a specific binding method.

In one embodiment, step S12 includes: generating second binding identifiers including the circuit board identifiers, the panel identifiers, and timestamps. This embodiment introduces the timestamps so that a binding time is traceable.

In one embodiment, step S12 includes: generating third binding identifiers including the circuit board identifiers, the panel identifiers, and binding machine identifiers. This embodiment introduces the binding machine identifiers so that binding machines are traceable.

In one embodiment, step S12 includes: generating fourth binding identifiers including the circuit board identifiers, the panel identifiers, timestamps, and binding machine identifiers. This embodiment introduces both the timestamps and the binding machine identifiers so that a binding time and binding machines are traceable.

S13: performing material management on the display panels according to the circuit board identifiers.

In one embodiment, performing a fully fitting process of covers; obtaining the circuit board identifiers; determining the panel identifiers based on the circuit board identifiers; and posting the display panels according to the panel identifiers.

The embodiment provides a novel method of managing materials, wherein in processes of manufacturing display devices, circuit board identifiers of flexible circuit boards and panel identifiers of display panels are obtained, and then the circuit board identifiers are bound with the panel identifiers. In a later stage, material management is performed on the display panels according to the circuit board identifiers. Due to uniqueness of the flexible circuit boards, sources of the display panels can be traced based on the circuit board identifiers. The aforementioned method is implemented without generating in-plant identification tags, so that no in-plant identification tags are needed to be sprayed on backlight plates of the display devices and no industrial inkjet printers are required, thereby overcoming a technical problem that industrial inkjet printers are required for conventional material management technology, and lowering costs of material management.

The present application further provides a device of managing materials. As shown in FIG. 2, the device 2 of managing materials includes: an obtaining module 21 configured to obtain circuit board identifiers of flexible circuit boards and panel identifiers of display panels from binding targets; a binding module 22 configured to bind the circuit board identifiers with the panel identifiers; and a managing module 23 configured to perform material management on the display panels according to the circuit board identifiers.

In one embodiment, the obtaining module 21 is configured to bind the flexible circuit boards and the display panels, and obtain the circuit board identifiers of the flexible circuit boards and the panel identifiers of the display panels.

In one embodiment, the obtaining module 21 is configured to package chips and the display panels to obtain first package bodies, and to package the flexible circuit boards and the first to obtain second package bodies.

In one embodiment, the binding module 22 is configured to encrypt the circuit board identifiers to obtain first encrypted identifiers, and to establish a first mapping relationship between the first encrypted identifiers and the panel identifiers, wherein the first encrypted identifiers are in a one-to-one correspondence with the panel identifiers in the first mapping relationship.

In one embodiment, the binding module 22 is configured to encrypt the panel identifiers to obtain second encrypted identifiers, and to establish a second mapping relationship between the circuit board identifiers and the second encrypted identifiers, wherein the circuit board identifiers are in a one-to-one correspondence with the second encrypted identifiers in the second mapping relationship.

In one embodiment, the binding module 22 is configured to establish a third mapping relationship between the circuit board identifiers and the panel identifiers, wherein the circuit board identifiers are in a one-to-one correspondence with the panel identifiers in the third mapping relationship.

In one embodiment, the binding module 22 is configured to establish a third mapping relationship between the circuit board identifiers and the panel identifiers, wherein the circuit board identifiers are in a one-to-one correspondence with the panel identifiers in the third mapping relationship. In this manner, no encryption process is required, ensuring binding speed.

In one embodiment, the binding module 22 is configured to generate first binding identifiers including the circuit board identifiers and the panel identifiers. This embodiment provides a specific binding method.

In one embodiment, the binding module 22 is configured to generate second binding identifiers including the circuit board identifiers, the panel identifiers, and timestamps. This embodiment introduces the timestamps so that a binding time is traceable.

In one embodiment, the binding module 22 is configured to generate third binding identifiers including the circuit board identifiers, the panel identifiers, and binding machine identifiers. This embodiment introduces the binding machine identifiers so that binding machines are traceable.

In one embodiment, the binding module 22 is configured to generate fourth binding identifiers including the circuit board identifiers, the panel identifiers, timestamps, and binding machine identifiers. This embodiment introduces both the timestamps and the binding machine identifiers so that a binding time and binding machines are traceable.

In one embodiment, the managing module 23 is configured to perform a fully fitting process of covers; obtaining the circuit board identifiers; determining the panel identifiers based on the circuit board identifiers; and posting the display panels according to the panel identifiers.

Take a total productive maintenance (TPM) finished product line operation process as an example to further explain this application in combination with specific application scenarios.

Conventional workflows include:

A binding stage (BD stage): a machine reads a panel identification (ID) of a cell panel, a system generates two-dimensional codes, and a printer prints the two-dimensional codes onto a protective film of a lower polarizer of the cell panel.

A full fitting stage process: the machine reads the two-dimensional codes on the protective film of the lower polarizer of the cell panel, obtains cell panel information by scanning, and performs system posting.

An assembly stage: the machine scans the protective film of the lower polarizer of the cell panel, the system obtains cell panel ID information, the protective film of the lower polarizer is torn off, a backlight plate is assembled, and a sprayer in the machine prints the generated cell panel ID onto the backlight plate.

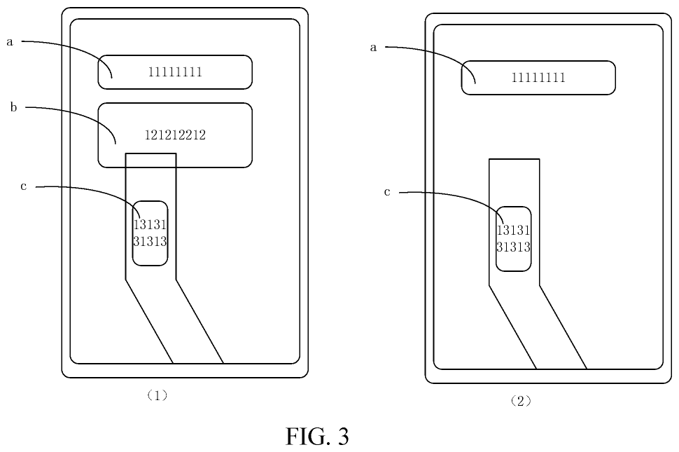

In this manner, the backlight plate as shown in FIG. 3 (1) includes a backlight plate identifier a, cell panel ID information b, and a circuit board identifier c of a flexible printed circuit board (FPC), wherein an area where the cell panel ID information b is stored interferes with a metal socket of the FPC that is prone to damage to in-plant codes.

An embodiment of the present application provides workflows including:

A binding stage (BD stage), including a first step, cell+integrated circuit (IC)→chip-on-glass (COG); that is, the IC is packaged on a cell panel to obtain COG (i.e. the above-mentioned first package body): a second step, COG+FPC→FPC on Glass (FOG); that is, the FPC is packaged on the COG to obtain the FOG (i.e. the above-mentioned second package body); a third step: a machine reads cell panel ID (i.e. the above-mentioned panel identifier) and FPC incoming material ID (i.e. the above-mentioned circuit board identifier), and a system binds the two ID information; and a fourth step: glue the FOG to produce a semi-finished FOG.

A full fitting stage, including soft items are adhered to hard items (optical clear adhesive (OCA) covers a cover glass (CG)), and hard items are adhered to hard items (CG covers FOG); the FPC incoming material ID is obtained by scanning through the machine; the bound cell panel ID is confirmed, thereby posting a display panel to produce a semi-finished product TPO.

An assembly stage, including a backlight plate assembly process, which is simplified by eliminating the need to scan two-dimensional codes on a protective film of a lower polarizer of the display panel through the machine, and a sprayer of the machine is used to print panel information onto the backlight plate to produce the finished TPM.

In this manner, the backlight plate as shown in FIG. 3 (2) includes a backlight plate identifier a, and a circuit board identifier c of the FPC, but cell panel ID information b is not included; FPC incoming ID information is used to replace backplate coding, and is capable of effectively identifying the panel information, thereby reducing production line loading and a risk of scratching due to interference between backplate codes and a FPC metal socket area.

That is, in this embodiment, the FPC incoming ID information is unique, and the panel ID information is unique. Therefore, only the two pieces of information need to be bound through the system, so that a purpose of providing a material code containing two types of material information can be fulfilled, thereby providing a method for replacing the backplate coding with the FPC incoming material code and for effectively identifying panel account information, further reducing production line loading and a risk of scratching due to interference between backplate codes and a FPC metal socket area.

According to the above-mentioned embodiment, the embodiment provides a novel method of managing materials, wherein in processes of manufacturing display devices, circuit board identifiers of flexible circuit boards and panel identifiers of display panels are obtained, and then the circuit board identifiers are bound with the panel identifiers. In a later stage, material management is performed on the display panels according to the circuit board identifiers. Due to uniqueness of the flexible circuit boards, sources of the display panels can be traced based on the circuit board identifiers. The aforementioned method is implemented without generating in-plant identification tags, so that no in-plant identification tags are needed to be sprayed on backlight plates of the display devices and no industrial inkjet printers are required, thereby overcoming a technical problem that industrial inkjet printers are required for conventional material management technology, and lowering costs of material management.

Accordingly, although the present invention has been disclosed as a preferred embodiment, it is not intended to limit the present invention. Those skilled in the art without departing from the spirit and scope of the present invention may make various changes or modifications, and thus the scope of the present invention should be after the appended claims and their equivalents.

What is claimed is:

1. A method of managing materials, comprising:
obtaining circuit board identifiers of flexible circuit boards and panel identifiers of display panels from binding targets;
binding the circuit board identifiers with the panel identifiers; and
performing material management on the display panels according to the circuit board identifiers.

2. The method of managing materials of claim 1, wherein the binding the circuit board identifiers with the panel identifiers comprises:
obtaining, by encrypting the circuit board identifiers, first encrypted identifiers; and
establishing a first mapping relationship between the first encrypted identifiers and the panel identifiers, wherein the first encrypted identifiers are in a one-to-one correspondence with the panel identifiers in the first mapping relationship.

3. The method of managing materials of claim 1, wherein the binding the circuit board identifier with the panel identifier comprises:
obtaining, by encrypting the panel identifiers, second encrypted identifiers; and
establishing a second mapping relationship between the circuit board identifiers and the second encrypted identifiers, wherein the circuit board identifiers are in a one-to-one correspondence with the second encrypted identifiers in the second mapping relationship.

4. The method of managing materials of claim 1, wherein the binding the circuit board identifier with the panel identifier comprises:
establishing a third mapping relationship between the circuit board identifiers and the panel identifiers, wherein the circuit board identifiers are in a one-to-one correspondence with the panel identifiers in the third mapping relationship.

5. The method of managing materials of claim 1, wherein the binding the circuit board identifier with the panel identifier comprises:
generating first binding identifiers comprising the circuit board identifiers and the panel identifiers.

6. The method of managing materials of claim 1, wherein the binding the circuit board identifier with the panel identifier comprises:
generating second binding identifiers comprising the circuit board identifiers, the panel identifiers, and timestamps.

7. The method of managing materials of claim 1, wherein the binding the circuit board identifier with the panel identifier comprises:
generating third binding identifiers comprising the circuit board identifiers, the panel identifiers, and binding machine identifiers.

8. The method of managing materials of claim 1, wherein the binding the circuit board identifier with the panel identifier comprises:
generating fourth binding identifiers comprising the circuit board identifiers, the panel identifiers, timestamps, and binding machine identifiers.

9. The method of managing materials of claim 1, wherein the obtaining circuit board identifiers of flexible circuit boards and panel identifiers of display panels from binding targets comprises:
binding the flexible circuit boards with the display panels; and
obtaining the circuit board identifiers of the flexible circuit boards and the panel identifiers of the display panels.

10. The method of managing materials of claim 1, wherein the performing material management on the display panels according to the circuit board identifiers comprises:
performing a fully fitting process of covers;
obtaining the circuit board identifiers;
determining the panel identifiers based on the circuit board identifiers; and
posting the display panels according to the panel identifiers.

11. A device of managing materials, comprising:
an obtaining module configured to obtain circuit board identifiers of flexible circuit boards and panel identifiers of display panels from binding targets;
a binding module configured to bind the circuit board identifiers with the panel identifiers; and
a managing module configured to perform material management on the display panels according to the circuit board identifiers.

12. The device of managing materials of claim 11, wherein the obtaining module is configured to bind the flexible circuit boards and the display panels, and obtain the circuit board identifiers of the flexible circuit boards and the panel identifiers of the display panels.

13. The device of managing materials of claim 11, wherein the obtaining module is configured to package chips and the display panels to obtain first package bodies, and to package the flexible circuit boards and the first to obtain second package bodies.

14. The device of managing materials of claim 11, wherein the binding module is configured to encrypt the circuit board identifiers to obtain first encrypted identifiers, and to establish a first mapping relationship between the first encrypted identifiers and the panel identifiers, wherein the first encrypted identifiers are in a one-to-one correspondence with the panel identifiers in the first mapping relationship.

15. The device of managing materials of claim 11, wherein the binding module is configured to encrypt the panel identifiers to obtain second encrypted identifiers, and to establish a second mapping relationship between the circuit board identifiers and the second encrypted identifiers, wherein the circuit board identifiers are in a one-to-one correspondence with the second encrypted identifiers in the second mapping relationship.

16. The device of managing materials of claim 11, wherein the binding module is configured to establish a third mapping relationship between the circuit board identifiers and the panel identifiers, wherein the circuit board identifiers are in a one-to-one correspondence with the panel identifiers in the third mapping relationship.

17. The device of managing materials of claim 11, wherein the binding module is configured to generate first binding identifiers comprising the circuit board identifiers and the panel identifiers.

18. The device of managing materials of claim 11, wherein the binding module is configured to generate second binding identifiers comprising the circuit board identifiers, the panel identifiers, and timestamps.

19. The device of managing materials of claim 11, wherein the binding module is configured to generate third binding identifiers comprising the circuit board identifiers, the panel identifiers, timestamps, and binding machine identifiers.

20. The device of managing materials of claim 11, wherein the binding module is configured to generate fourth binding identifiers comprising the circuit board identifiers, the panel identifiers, timestamps, and binding machine identifiers.
